(19) United States
(12) Patent Application Publication
(10) Pub. No.: US 2008/0314441 A1
(43) Pub. Date: Dec. 25, 2008

(54) Structure With Profiled Surface for Variable Visual Effects

(75) Inventor: William David Mather, Monmouth (GB)

Correspondence Address: Novak Druce + Quigg, LLP, 1300 Eye Street, NW, Suite 1000, Suite 1000, West Tower, Washington, DC, 20005, US

(73) Assignee: CORUS LIMITED, London (GB)

(21) Appl. No.: 12/090,090

(22) PCT Filed: Oct. 12, 2006
(86) PCT No.: PCT/EP2006/009868

§ 371 Date: Sep. 4, 2008

(30) Foreign Application Priority Data
Oct. 12, 2005 (EP) 05077330.8

(51) Int. Cl. H01L 31/00; B32B 3/30; B21B 1/00

(52) U.S. Cl. 136/252; 428/167; 72/365.2

(57) ABSTRACT

A structure, substrate or other article having a profiled surface comprising a plurality of profiled, in a length direction extending ridges, each ridge having a peak and on opposite sides of the peak a sloping side and an opposite, downwardly directed side, wherein the downwardly directed side comprises an undercutting part which is directed back under the peak of the ridge and wherein the undercutting part extends from a most forward point where the undercutting starts to a valley, wherein 0.1 M≦d≦0.9 M, wherein M is the distance between the most forward point of the peak and the sloping side or an imaginary extension thereof and d is the largest distance in a plane perpendicular to the length direction between the downwardly directed side and a line drawn perpendicular to the sloping side, or extension thereof, and connecting to the most forward point.

The invention relates to a structure, substrate or other article having a profiled surface comprising a plurality of profiled, in a length direction extending ridges, each ridge having a peak and on opposite sides of the peak a sloping side and an opposite, downwardly directed side, wherein the downwardly directed side comprises an undercutting part which is directed back under the peak of the ridge and wherein the undercutting part extends from a most forward point where the undercutting starts to a valley.

Generally the walls and ceilings of a building are flat. Similarly billboards and similar sign faces are generally flat. Whether these are plain-coloured or patterned or portray an image, they give basically the same visual effect from whichever aspect or angle they are viewed.

U.S. Pat. No. 6,001,456 discloses a doormat showing a plurality of ridges each having a sloping side and a downwardly directed side. The sloping sides, and the downwardly directed sides are provided with a first and second text respectively. When looking at the sloping sides, at a given viewing angle the first text on these sides can be read, when looking at the downwardly directed sides at another angle the second text can be read.

In order to improve the visual effect of a structure, substrate or article, WO 2004/042167 A1 (PCT/GB2003/004289) proposes to provide the downwardly directed side with an undercut part, which is directed back under the peak where the sloping side and the downwardly directed side meet. The object is to achieve that if the surface of the structure, substrate or article is seen from one direction, the sloping side of the ridges will be seen and the inwardly and downwardly directed sides of the ridges will be hidden, especially because of the undercut profile. If the surface is viewed from the opposite direction than the undercut, inwardly directed sides of the ridges will be seen and the sloping sides will be substantially hidden.

Furthermore GB 2382053 A has disclosed a structure, substrate or article having a surface formed with a series of profiled ridges, each ridge having a sloping side and an opposite downwardly directed side. In the embodiments shown a peak connecting a sloping side to the downwardly directed side of a ridge has a convex curved region. The downwardly directed side does not have an undercut part.

A general object of the present invention is to improve the viewing properties of a structure, substrate or other article providing a visual effect, when observed from different viewing angles, in particular when observed from a continuously running viewing angle.

It is an object of the present invention to provide a structure, substrate or other article which provides a visual effect which has the attraction that it varies in a smooth and pleasant-to-the-eye way with the viewing angle.

It is a further object of the present invention to provide a structure, substrate or other article having an improved transition from one image to the other image when varying the viewing angle.

It is another object of the present invention to provide a structure, substrate or other article, which gives a better display of the images over a wider range of viewing angles.

It is another object of the present invention to provide such relief pattern or profiled surface, the effect of which is independent of whether it is the observer or the object that moves.

It is still a further object of the present invention to provide a relief pattern or profiled surface which allows a great flexibility in the manner in which the images that can be observed from different viewing angles, can be applied or projected to or onto the relief pattern or profiled surface.

It is further object of the invention to provide a relief pattern or profiled surface, which can be manufactured from a wide range of materials.

It is yet a further object of the present invention to provide a relief pattern or profiled surface, which is cheap to manufacture, which can be manufactured in a wide variety of sizes dependent on the application or can be assembled to the desired size by coupling sub-assemblies.

According to a first aspect of the present inventive concept, in particular in view of observing a smooth transition that is also pleasant to the eye, a structure, substrate or other article having a profiled surface is provided comprising a plurality of profiled, in a length direction extending ridges, each ridge having a peak and on opposite sides of the peak a sloping side and an opposite, downwardly directed side, wherein the downwardly directed side comprises an undercutting part which is directed back under the peak of the ridge and wherein the undercutting part extends from a most forward point where the undercutting starts to a valley, wherein 0.1 M≦d≦0.9 M, wherein M is the distance between the most forward point of the peak and the sloping side of an adjacent ridge or an imaginary extension thereof and d is the largest distance in a plane perpendicular to the length direction between the downwardly directed side and a line drawn perpendicular to the sloping side of the adjacent ridge or extension thereof, and connected to the most forward point.

The profiled surface of the structure, substrate or other article accordingly provides a different visual effect depending from which direction it is viewed. If the surface is viewed from one direction, then the sloping sides of the ridges will be seen and the opposite, downwardly directed sites of the ridges will be hidden, especially because these sides partially undercut the peaks of the ridges. If the surface is viewed from a direction facing the downwardly directed sides, the undercutting sides will be seen and the sloping sides will totally or substantially be hidden. With the profiled surface according to the invention it has proved possible to ensure that the observer sees a very striking colour, pattern or image transition (or transitions) as the undercut, hidden side (or sides) come into view and, in turn, different areas or regions become hidden.

The undercut nature, preferably having a concave shape, of the downwardly directed sides allows any pattern, colour or image on these sides to be at least partially hidden from an observer standing directly in front of the profiled surface. Hence, if a different pattern, colour or image is applied to the sloping sides, then, as an observer's viewing angle changes from one side of the profiled surface to the other, the pattern, colour or image changes gradually in a fashion that has proven to be very striking and very pleasant-to-the-eye.

The invention is based on the notion that for a smooth and pleasant-to-the-eye transition from a first image, on the sloping side, to a second image, on the undercutting downwardly directed side, the second image should be incrementally revealed with varying viewing angle and also that each increment is revealed at an angle that is favourable to easy observation.

In case the downwardly directed side is not undercut as disclosed in GB 2382 053, with a small change of viewing angle the observer can look past the peak and see the downwardly directed side, with immediate revelation to the observer of the full, second, image on that side.

The immediate revelation of the second image and the fact that the second image is observed under a very acute angle confuses the observer and makes the transition from the first image to the second image unpleasant to the eye.

When the downwardly directed side is undercut, the observer will only see a small portion of the second image when passing the peak. With increasing viewing angle, an increasing portion of the second image is revealed which gives the observer the sensation of a smooth transition from the first image to the second image, which is pleasant to the eye.

According to the invention, as each incremental new section of the second image comes into view, as the observer progressively changes the viewing angle, the viewing angle of that particular section with respect to the observer is not very acute and therefore any portion of the second image, placed on that section is recognisable to the observer.

Furthermore, as each new section, carrying a portion of the second image, is revealed, its position with respect to the plane of the overall structure, substrate or other article is changed. This is believed to confer an apparent three-dimensionality to the transition from the first image to the second image.

Control of the shape of the downwardly directed side can greatly improve the aforementioned effects.

Tests have shown that good results are obtained when 0.1 M≦d≦0.9 M. Meeting this condition ensures that an incremental revelation of the second image to the observer is achieved, and that the observer is not confused during the transition of the first image to the second image. Further, under the given condition, the second image is recognisable over a wide range of viewing angles.

Where d>0.9 M, the undercutting part becomes too deep to achieve an effective coherent image when the observer views the surface of that part.

The viewing angles over which an observer typically sees good recognisable images on normal flat signs ranges from about −45° to about +45°.

With a deep undercutting part, the proportion of the surface that is presented to the viewer at an angle within the range of between −45° to +45° becomes smaller, hence making it difficult for the observer to recognise a coherent image. Also, with deep undercutting there can only be a narrow range of angles over which there is any possibility of forming a coherent image.

Where d<0.1 M, the profile of the undercutting part begins to approximate a straight line with the drawback that there is little or no hidden proportion of the second image. Hence the attractiveness of the transition of the first image to the second image is greatly reduced because the image on the only slightly curved undercutting part is not sufficiently incrementally revealed.

Furthermore, there is little or no additional surface area available for the second image as compared to a version wherein the downwardly directed side follows a straight line.

Preferably, the undercutting part of the downwardly directed side is curved, and good results are obtained where the undercutting part of the downwardly directed side is concave-curved.

In a preferred embodiment 0.1 M≦d≦0.6 M, preferably 0.1 M≦d≦0.4 M. In this embodiment, the surface of the undercutting part is of a generally circular nature, which gives optimum revelation of the second image for a wide range of viewing angles. Best results are obtained in the more preferred range wherein 0.1 M≦d≦0.4 M.

The concave nature of the downwardly directed side increases the area available for display of any pattern, colour or image on these sides, compared to a less curved side. An increase up to 57% has shown to be possible.

A concave shape of the valley at the bottom of the downwardly directed side, provides that greater evenness of light reflection is available to the observer, when compared to light reflection available from a less curved side that is conjoined at an angular interface. Distinct shadow lines in the valley are therefore reduced or completely eliminated.

At the peak, the sloping side and the downwardly directed side may meet at an acute angle to each other.

According to a second aspect, in particular in view of a smooth transition the present inventive concept relates to a structure, substrate or other article having a profiled surface comprising a plurality of profiled, in a length direction extending ridges, each ridge having a peak and on opposite sides of the peak a sloping side and an opposite, downwardly directed side, wherein the downwardly directed side comprises an undercutting part which is directed back under the peak of the ridge and wherein the undercutting part extends from a most forward point where the undercutting starts to a valley, wherein the sloping side and the downwardly directed side are connected at the peak by a curved transition region extending between the sloping side and the undercutting part.

This embodiment affords greater smoothness to the transition from the first to the second image. This occurs because, when the observer's viewing angle changes, the transition is introduced gradually and smoothly, rather than at a sharp point.

One reason for this is that the curved transition region provides that the peak of the ridge is less distinct to the observer compared to sharp transition. Therefore, when an image is placed on the sloping side, it is less obvious to an observer that the viewed surface is in fact profiled, hence introducing a surprise element when an image appears.

The curved transition region also reduces the distinctness of any shadowing that occurs under the peak when compared to a shadow that would be cast by a sharp transition as light follows round the curved transition region. This less distinctness of the shadowing also reduces the visibility of the transition region and gives the structure, substrate or other articles the appearance that they are flatter than the articles known from the prior art. Hence, the curved transition region contributes to a surprise element of the transition of a first image to a second image.

The curved transition region also has a favourable effect on the transition of the second image, placed on the undercutting part, to the first image, placed on the sloping part.

Where the peak has a sharp edge, when the observer moves in the direction of the sloping side, a sudden transition of the images occur.

Where the peak has a curved transition region, at the initial point of the transition, the first image is momentarily, incrementally revealed when the viewing angle at which the observer looks at the first image increases. Hence the observer experiences a smoother start to the transition from the second image to the first image.

Preferably, the first and the second images are joined about in the middle between the highest point and the most forward point.

In case the sloping side and the downwardly directed side would meet at a sharp peak, the images would be joined at the precise peak and the alignment of the two images is critical to prevent indistinctness of the interface.

A curved transition region allows for more tolerance of the alignment without running the risk of a distinct visible interface.

Preferably, the curved transition region is convex curved,

Preferably the structure, substrate or other article according to the second aspect of the present inventive concept has aconvex curved transition region with a radius R which satisfies the condition 0.05 M≦R≦0.25 M, wherein M is the distance between the most forward point of the peak and the sloping side of an adjacent ridge or an imaginary extension thereof. If the magnitude of the radius is too small, the benefits of a curved transition region become minimal. If the magnitude of the radius is too large, significant areas of the second image, placed on the downwardly directed side can not be sufficiently hidden from being viewed over a wide range of viewing angles and complete coherent images would only be seen from the most acute viewing angles, between the direction of observation and the plane in which the structure, substrate or other article extends.

Optimum benefits are obtained in an embodiment wherein 0.05 M≦R≦0.15 M.

Preferably there are no sharp changes of direction in the sloping side, the downwardly directed side or at the interface of the sloping side and the downwardly directed side.

The sloping side may be gently curved. In that case, for construction of the line perpendicular to the sloping side, the chord that joins the two ends of that curve is deemed to represent the sloping side.

Preferably, the sloping side is flat, blending into curves at each end i.e. between two successive downwardly directed sides.

The use of curves at the interface of the sloping sides and the downwardly directed sides provide the manufacturer or user with improved control over any transition in patterns, colours or images placed on the sloping sides and the downwardly directed sides that can be observed with varying viewing angle.

The present inventive concept is also embodied in a structure, substrate or other article having a profiled surface comprising a plurality of profiled, in a length direction extending ridges, each ridge having a peak and on opposite sides of the peak a sloping side and an opposite, downwardly directed side, wherein the downwardly directed side comprises an undercutting part which is directed back under the peak of the ridge and wherein the undercutting part extends from a most forward point where the undercutting starts to a valley, wherein the acute angle T between a line connecting lowest points of successive ridges on the one hand and the direction of the sloping side on the other hand satisfies the condition 15°≦T≦40°.

It has been found that the angle T is important for the sensation of a changing image when varying the viewing angle.

Where T<15°, the display area, on the downwardly directed side becomes too small to provide a good display and the viewing angle required for an observer to see a coherent image on that side becomes too acute.

Where T increases above 40°, two specific problems occur.

Firstly, the opportunity to hide any significant part of the image on the downwardly directed side becomes more difficult or impossible, leading to an ineffective, less surprising incremental revelation of that image. Secondly, the ridges progressively become more discernable, which is detrimental to the apparent flatness of the structure, substrate or other article when viewed from the sloping side and hence detrimental to the surprise when the image changes as the observer passes.

Optimum effects are obtained in an embodiment T satisfies the condition 20°≦T≦25°.

As already stated the sloping side may be gently curved. In that case, the direction of the sloping side is to meant to be the direction of the chord that joins the two ends of the curved sloping side.

For a good visual effect it is preferred that the sloping side and the downwardly directed side of at least one ridge present at least partly coloured or patterned areas or images in a contrasting manner.

The sloping side and the downwardly directed side may be plain, coloured, patterned or have an image, applied by any method in a contrasting manner.

The respective area of each ridge may be coloured or patterned in a contrasting manner. The respective areas may be provided with plain colours or tones, or with patterns. Instead, either the sloping or the downwardly directed sides of the ridges (or both sides thereof) may be provided with colouring which forms a pictorial image, e.g. of figurative, landscape or architectural nature.

The sloping side and/or the downwardly directed side of a plurality of ridges may have the same colours or pattern or the colour or pattern may vary from ridge to ridge or from one series of adjacent ridges to a second series of adjacent ridges, dependent on the effect to be obtained.

The sloping sides and/or the downwardly directed sides may be provided with colouring or patterning which form a pictorial image.

The image may be formed by applying, by any method, sections of the image to different ridges so that, when viewing from one side, the complete image is observed.

An embodiment enabling to obtain additional surprising effects is characterised in that at least one downwardly directed side or sloping side has regions with distinct optical, physical or mechanical properties.

In this embodiment the observed image seen on the sloping side or the downwardly directed side can be interrupted or varied over a selected range of viewing angles giving rise to an additional optical effect. It is possible to reflect through optical means a portion of an image such that it can be seen only over a limited range of viewing angles or a mechanical perturbation can be applied to a side such that it can only be seen in a limited range of viewing angles.

A wider range of effects can be obtained with an embodiment of the invention which is characterised in that the pitch and/or the shape and/or the optical properties and/or the material of the ridges present on the profiled surface vary with the position of the ridges in the structure, substrate or other article.

In this embodiment successive changes in the images seen by the observer occur when the viewing angle is changed through relative movement of the profiled surface and the observer.

The structure, substrate or other article may be manufactured through extrusion of a metal, preferably aluminium or a polymeric material.

Extrusion is a very effective method of producing profiled, mainly flat panels within a wide range of widths and lengths. The method is particularly suitable for making profiled surfaces.

Aluminium has the advantage of lightweight. Polymeric material can be translucent or coloured and are cheap to process. Extrusion technology for aluminium and polymeric material is well known to the skilled person and does not need further elaboration.

Alternatively, the profiled surfaces can be manufactured from low carbon steel or stainless steel. Low carbon steel combines high strength for self supporting profiled surfaces with low price and good processability like forming and coating with the desired colour, pattern or image.

Stainless steel has the advantage of high corrosion resistance for most applications of profiled surfaces according to the invention.

An embodiment with great flexibility in application is characterised in that the structure, substrate or other article is applied to a carrier whereby the structure, substrate, other article is at least for a part translucent and whereby between the carrier and the structure, substrate or other article a coloured pattern or image bearing intermediate layer is applied.

In this embodiment the same profiled surface can be used for a wide variety of applications by simply changing the intermediate layer. Also the image is protected from outside harmful influences like weather or vandalism, which makes the profiled surface more robust.

Coloured, patterned or image bearing areas may be embedded in at least one of the sloping sides and/or downwardly directed sides.

This embodiment is of particular interest in the case wherein a translucent material is used. It is possible to embed in a single manufacturing process step, such as vacuum forming, the desired coloured or patterned areas or images.

A particularly versatile embodiment of the invention is characterised in that the structure, substrate or other article is provided with means for projecting coloured or patterned areas on at least one of the sloping sides and/or downwardly directed sides.

Use can be made of a blank or equally coloured or patterned profiled surface on which the desired colour, pattern or image is projected. By changing the projected image, the visual appearance of the profiled surface can easily, quickly and cheaply be changed.

In applications wherein a large area of profiled surface is required, an embodiment of the invention is characterised in that the structure, substrate or other article has the form of a panel and at least two panels are provided with coupling means for coupling two or more panels is beneficial. Also changes or repairs can easily be made without having to change or replace the whole structure, substrate or other article.

At least one of the downwardly directed side and sloping side of at least one ridge may be provided with a photovoltaic element.

Profiled surfaces are often exposed to light, in particular in outside applications. Incident light can effectively be converted in electrical energy.

In a particular embodiment wherein the photovoltaic element is applied in the undercut downwardly directed side is of interest since incident light is to a large extent absorbed by the folded back side and converted into electrical energy, whilst the sloping sides can be used to provide the observer with aesthetic appearances different to that of the photovoltaic elements.

The principles of the invention may be applied to interior or exterior walls of a building, with the ridges extending vertically, so that a varying visual effect is provided depending upon the end from which the observer views the surface. Particularly where the surface is provided with pictorial images, an impression of movement may be created as the observer passes along the wall.

The principles of the invention may, however, be applied to a variety of other structures, substrates or articles, including display signage, ceilings, roofs, floors and articles of furniture.

The relief pattern or profiled surface may be formed directly on the surface of a wall or other structure, or onto panels which can then be used in the construction or cladding for that structure.

The ridges may be formed integrally with the structure, substrate or other article, or may comprise separate elements (e.g. pre-formed strips) applied to a planar surface.

The structure, substrate or other article may be formed of a variety of materials, including plaster, polymeric material, glass and metal.

Any colouring or pattern may be applied to the surface after its formation, whether manually, by machine, by projection or other technique. Instead, the colouring may be incorporated into the materials of the structure, substrate or other article before or during its formation. Varying visual effects and surprising transitions associated with interference effects and depending on viewing angle, can be created when transparent or translucent materials are used to create profiles conforming to the current invention.

As a significant aspect of the current invention is associated with images, colours and patterns, innumerable techniques associated with lighting can be used as enhancement or integral part of structures, substrates or articles that conform to this invention. These include coloured lighting, projected lighting, back lighting and lasers.

The invention is also embodied in a method for the manufacture of a structure, substrate or other article according to the invention wherein a sheet or strip shaped product is rolled into the structure, substrate or other article.

In this embodiment, long panels can be manufactured with any suitable pitch between the ridges with simple rolling or roll-forming equipment.

Prior to rolling, the sheet or strip shaped product may be provided with a coloured, patterned or image bearing layer or a photovoltaic elements comprising layer such that after rolling a desired optical or photovoltaic effect is achieved.

This embodiment has the advantage that in a single process step, the sheet is formed and covered with the desired layer.

The skilled person will understand that it is possible to provide the structure, substrate or other article with an undercutting part satisfying the condition 0.1 M≦d≦0.9 M with any shape of the peak or with any value of the angle T as described in this application.

Equally, the skilled person will understand that it is possible to provide the peak with a curved transition region while the undercutting part has any shape or the angle T as described in this application has any value.

Further, the skilled person will understand that it is possible to give the angle T as described in this description, a value in the range mentioned above while the undercutting part has any form or the peak has any shape.

It is preferred that the structure, substrate or other article according to the invention has more than one, preferably all three aspects of the inventive concept mentioned above or an embodiment thereof.

Embodiments of the present invention will now be described by way of examples only and with reference to the accompanying drawing in which

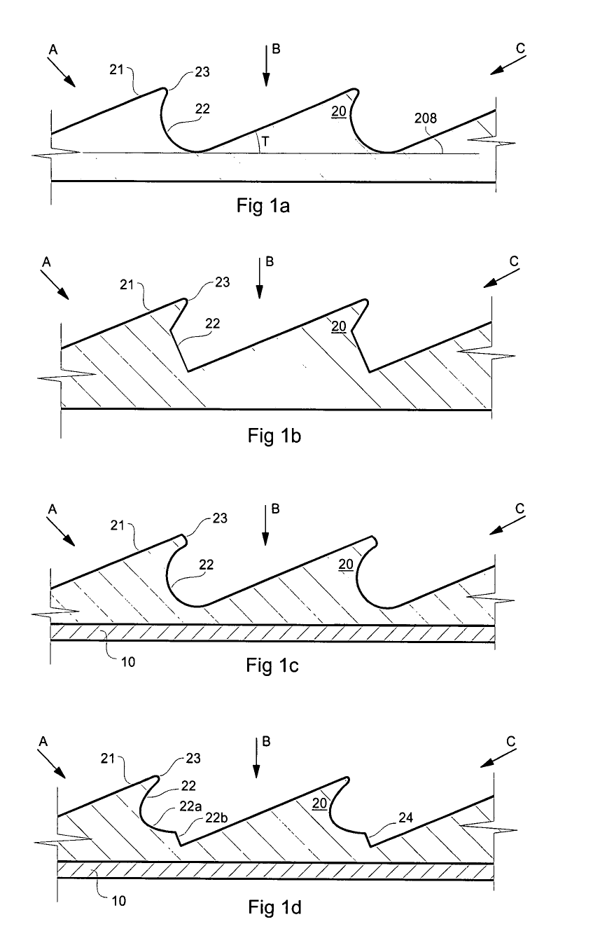

FIG. 1 shows a sectional view of some embodiments of a structure, substrate or other article according to the invention.

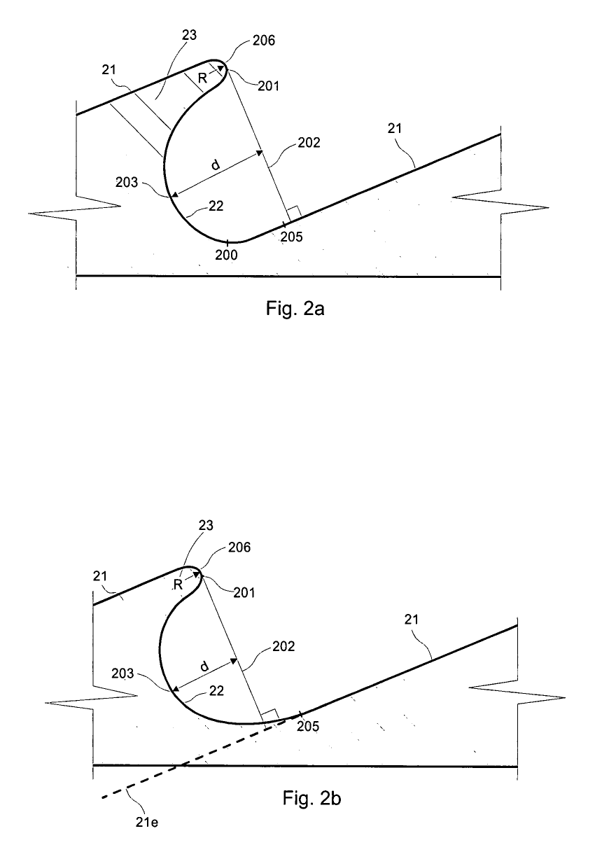

FIGS. 2a, 2b and 2c show on an enlarged scale a part of an embodiment shown in FIG. 1.

FIG. 2d shows in a sectional view a structure having a deep undercutting downwardly directed side.

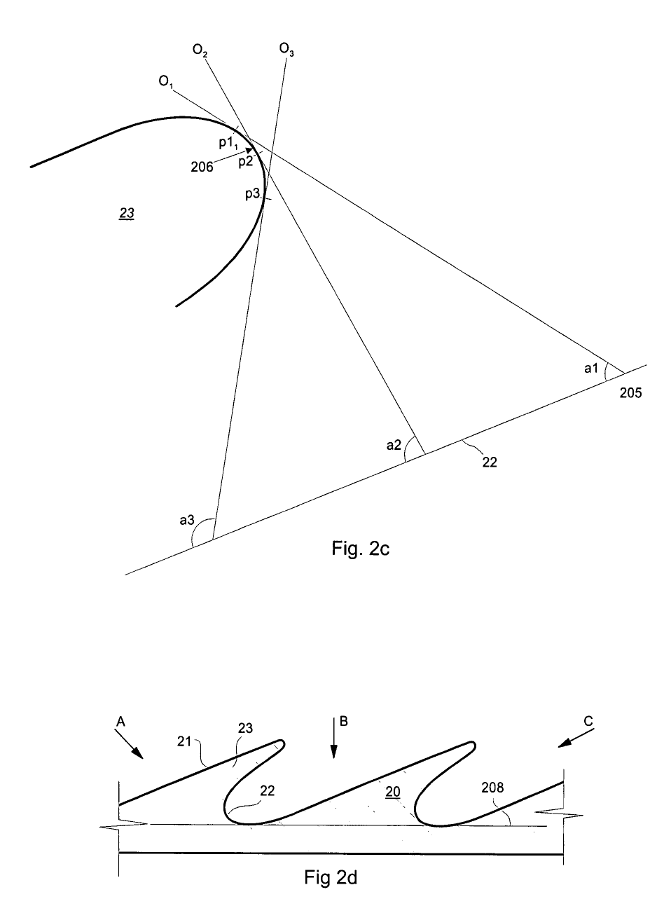

FIG. 3 shows a sectional view of some embodiments of a structure, substrate or other article according to the invention having images applied to it.

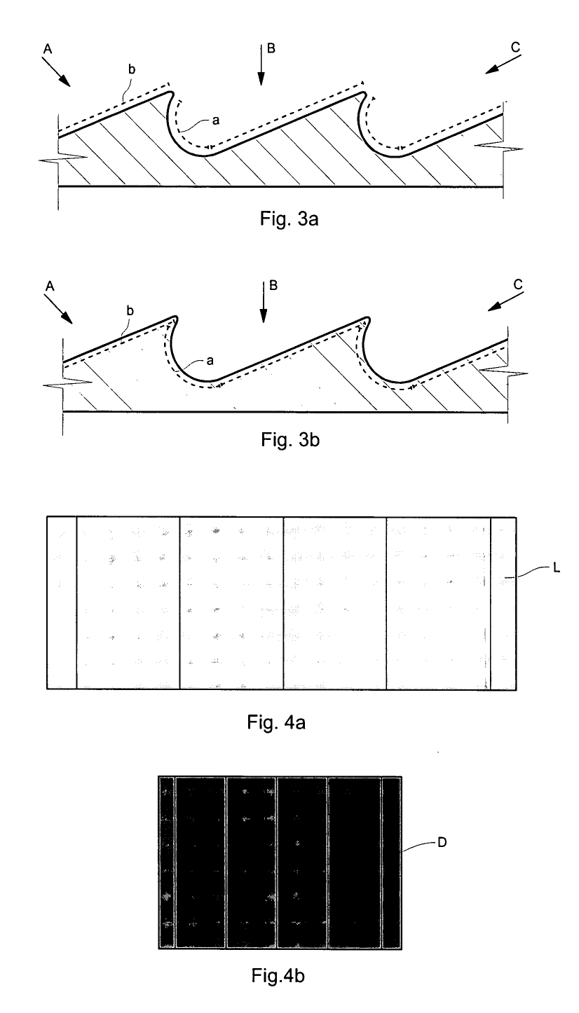

FIG. 4 shows a view of a structure, substrate other article as shown in FIG. 2 from two different angles.

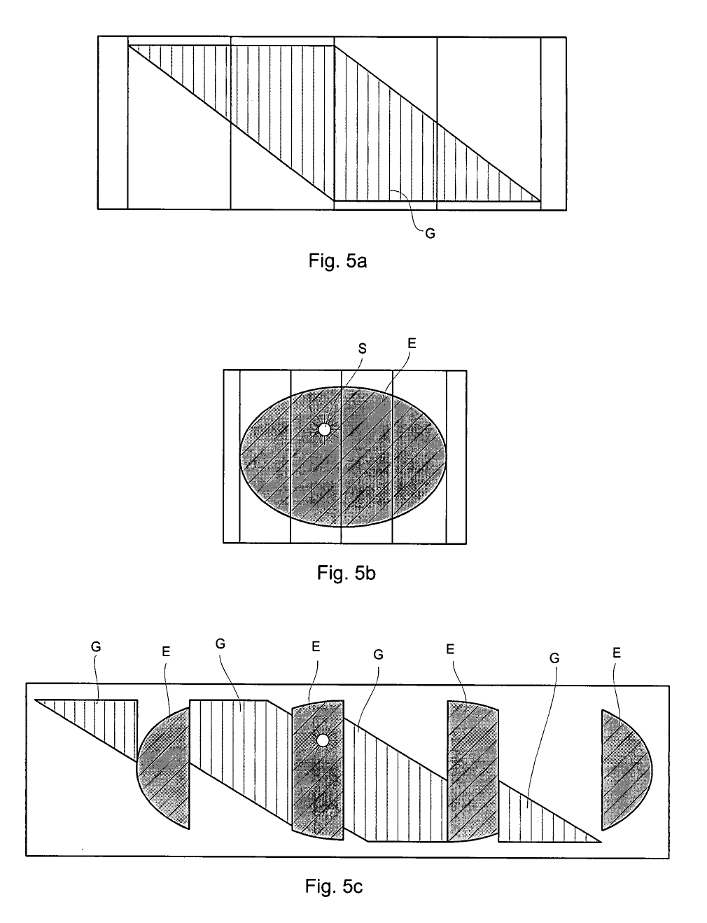

FIG. 5 shows a view of a structure, substrate or other article according to the invention, showing two different images seen from two different angles and a view of two combined images prior to application to the structure, substrate or other article.

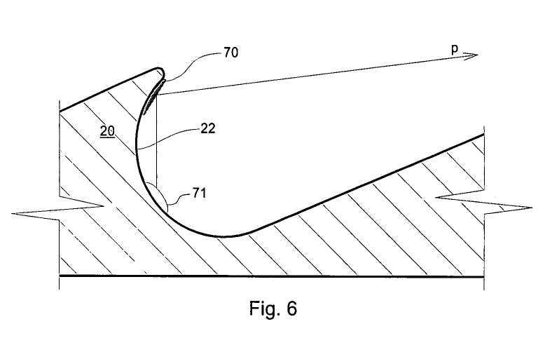

FIG. 6 shows schematically a cross section of a structure, substrate or other article according to the invention wherein a different image can be observed within a limited range of viewing angles.

Referring now to FIG. 1, there are shown four examples of a structure, substrate or other article having a profiled surface according to the invention. The profiled surface has a plurality of wave-shaped ridges 20, each comprising a sloping side 21, and an opposite downwardly directed side 22, which is directed back or undercuts the peak 23 of the ridge. The undercutting side of a ridge merges with the sloping side of the adjacent ridge. The peak has the shape of a curved transition region joining the sloping side 21 with the downwardly directed side 22. The downwardly directed side is at least partly re-entered (undercutting) with respect to its side of the ridge.

Each ridge thus has a sloping side 21, which is inclined at a relatively small or acute angle to the general plane of the structure, substrate or other article and an opposite side 22 which curves downwardly and sloping under the peak 23 of the ridge, then extends forward to merge with the commencement of the sloping side 21 of an adjacent ridge. The sloping and downwardly directed sides preferably meet at peak 23 in the shape of a curved transition region which overlies at least the adjacent part of side 22.

The profiled surface can be integral with the structure, substrate or other article or it can be a separate layer mounted on a carrier 10 as shown in FIGS. 1c and 1d.

As shown in FIG. 1d, the downwardly directed side can be composed of more than one different shape, such as a curved shape 22a connected to a plain shape 22b.

In FIG. 1a the lowest points of the ridges have been connected by a virtual line 208. The general direction of the sloping side 21 meets the virtual line 208 at an angle T. According to an embodiment of the inventive concept the angle T meets the condition 15°≦T≦40°.

This embodiment creates, when different images, colours or patterns are applied to the surfaces of the respective shapes, different visual effects.

The different visual effects can be observed when the viewing angle changes from position A to position C through position B as will be explained later.

FIGS. 2a, 2b and 2c show on an enlarged scale details of the ridge of the embodiment shown in FIG. 1a.

In FIG. 2a the valley of the undercutting part is indicated by reference numeral 200, the most forward point where the undercutting starts is indicated by reference numeral 201. A virtual line 202 is drawn perpendicular to the sloping side 21 of an adjacent ridge such that it connects with most forward point 201. The length of the virtual line 202 is M. Reference numeral 203 indicates the point of the downwardly directed side 22 furthest away form the virtual line 202. The distance between the point 203 and virtual line 202 is indicated by d.

FIG. 2b shows another embodiment of the invention wherein the shape of the downwardly directed side and the sloping side are such that the line 202 intersects extension 21e of the sloping side 21 of the adjacent ridge 20.

According to one aspect of the invention the relation between d and M satisfies the condition 0.1 M≦d≦0.9 M.

In FIGS. 2a and 2b the peak 23 has the form of a curved transition region. The curved transition region generally follows the shape of a circle with radius R. According to one aspect of the invention 0.05 M≦R≦0.25 M.

FIG. 2c shows on a further enlarged scale a detail of the peak 23 and part of the sloping side 21 (not to scale).

The second image extends over the downwardly directed side from position 205, which may be on the sloping side to position 206, which is on the curved transition region.

As can be seen from this figure, when an observer moves from position 1, indicated by O1, through position 2, indicated by O2 to position 3, indicated by O3, not only the viewing angle, indicated by a1, a2, a3 respectively changes, but also the point at which the observer sees the peak changes from p1, through p2 to p3, resulting in two effects.

Firstly the observer sees the peak 23, here in the form of a curved transition region, at a varying position and not as a fixed point.

Further, the changing position of p1, p2 and p3 contributes to the incremental revelation of the second image.

These two effects are suspected to contribute considerably to a smooth transition from the first image to the second image.

FIG. 2d shows the effect of a deep undercutting of the downwardly directed side. Viewing in the direction of arrow C, which equals angle T, the undercutting downwardly directed concave sides can be seen. However, changing the direction of viewing over just a few degrees in either direction will make most or all of the image on the concave surface disappear. Therefore, the undercutting should not be too deep. Best results are obtained with an undercutting according to the present inventive concept.

FIG. 3 shows the embodiment A of FIG. 1, but now with a colour, pattern or image applied to it.

In FIG. 3, section b (dotted line b) indicates a first colour, pattern or image or part thereof applied to the sloping side at the ridge or ridges, section a (dotted line a) indicates a second colour, pattern or image or part thereof applied to the downwardly directed side of the ridge or ridges.

As can be seen from FIG. 3 b, the different colours, patterns or images can be applied to the surface of the ridges, but can also be embedded in or under the, translucent, ridges, which protects them from outside influences.

FIG. 4 shows a top view of a structure, substrate or other article as depicted in FIG. 3, but seen from two different angles. This figure shows the change of colour or pattern or images, which is achievable dependent on the viewing angle using a profiled surface in accordance with the current invention.

In the example shown in FIGS. 3 and 4, different areas of the profiled surface are of contrasting colours or patterns. In particular, an area of relatively light colour L (indicated by light grey shading in FIG. 4 a; section b in FIG. 3) extends over the sloping side 21 up to the peak 23 of each ridge 20; an area of relatively dark grey shading D (FIG. 4 b, section a in FIG. 3) extends from the peak 23 of each ridge 20, down over its concave-curved surface 22 to the commencement of the sloping side 21, or just prior to or just past it, of the adjacent ridge.

The substrate accordingly provides a different visual effect to an observer, depending upon the viewing angle. Thus, if the substrate is viewed from the direction of arrow A or B in FIG. 3, then the observer will only or predominantly see the lighter areas b, L of the sloping sides 21 of the ridges 20; the darker areas a, D of the downwardly directed surfaces 22 of the ridges will be substantially or entirely hidden, because of the undercut concave-curved profile of these surfaces, which provide that the peaks 23 overlie at least the adjacent parts of the surfaces 22. Likewise, if the substrate is viewed in the direction of arrow C in FIG. 3, then the observer will see, predominantly or entirely, the darker areas a, D of the concave-curved surfaces 22 and end edges 23 of the ridges 20.

Instead of using light and dark coloured (or patterned) areas, an example of a very effective embodiment is where pictorial images are used. An example of an image, which may be, for example, printed onto a vinyl film prior to applying to a profiled surface, is shown in FIG. 5. Here the images of an ellipse and a diamond have been split and printed onto a strip of vinyl such that the vinyl or other suitable material (see FIG. 5 c) can be overlaid onto a profiled surface. In this example, with reference to FIG. 3, the vinyl would be carefully applied such that all the separate elements of the ellipse's image, E, would fall on sequential downwardly directed concave sides 22. The elements of the diamond, G, would be applied to sloping sides 21. In this way, an observer looking from position A could see a fully coherent image of the diamond, whilst the image of the ellipse would be completely hidden from view. When the observer moved to position C, only a fully coherent image of an ellipse could be seen. As the viewer passes from one side to the other, the transition from one image to the other is exceptionally visually striking. This results from the undercut nature of part of the downwardly directed side, in particular a concave curved side, which serves initially to hide the image of the ellipse but then, as the observer passes by, the image of the ellipse is rapidly and incrementally revealed as the image of the diamond disappears from view. The effect also benefits from the increased surface area provided by the sloping and curved surfaces, compared to a flat panel.

The substrates that have been described may form a wall of a room, with ridges running vertically and/or horizontally or a ceiling. It is also possible to apply the profiled surface according to the invention to a curved, not plain, carrier or backing structure. Also in such case, the substrate will provide its different visual effects to an observer, depending on viewing angles.

The principles of the invention may be applied to the surface of an enormous variety of articles, including signs, furniture and appliances. The structure, substrate or other article may comprise a flat panel onto which the profiled surface is applied. The profiled surfaces of the structure, substrate or other articles or the substrate carrying the profiled substrate or other articles may be formed of a wide variety of materials, including plaster, glass, polymer material, metal such as aluminium, steel or stainless steel, concrete and foam.

The colouring patterns or images for the different areas may be applied to the structure, substrate or other article, after it has been manufactured, for example by painting, spraying or otherwise. The image instead may be projected onto the surfaces. Instead, the image may be applied to the underside of a transparent or translucent profiled sheet. Instead, the colouring may be incorporated into the material of the structure, substrate or other article or of the ridge during the course of its manufacture.

For example, the colouring or pattern may be carried on a sheet or film of polymeric material, which is then superimposed over the front surface of a substrate pre-formed with a series of wave shaped ridges. The sheet or film is then applied to the substrate under heat and pressure, to deform the sheet or film to conform to the surface relief profile of the substrate. The sheet or film could be bonded to the substrate by means of adhesive carried on or applied to either the underside of the sheet or the front surface of the substrate. The colouring, pattern or image may be applied to the front surface of the sheet or film, before it is applied to the substrate, by any suitable means, for example printing by offset litho printing or screen printing. The sheet is registered in position relative to the substrate, before application thereto, to ensure the successive contrasting colours on the sheet are registered to the opposite sides of the successive ridges of the substrate. The ratio between the section applied to the sloping side and the downwardly directed side preferably is between 1 to 0.3 and 1 to 0.8, more preferably between 1 to 0.4 and 1 to 0.6.

Moreover, variations on the basic profiled surface having a downwardly directed, undercut side can be used for different or enhanced effects, but all have a common feature that some part of the downwardly directed side is totally hidden from the view of an observer positioned directly in front of a series of ridges. For example, the shape or material properties of such ridges may be varied along the length of individual ridges or they may vary from ridge to ridge along a series of ridges. A further example is an arrangement to achieve more than one transition of images as the observer's viewing angle changes. With reference to FIGS. 6 and 3, a perturbation 71 within the curve of a downwardly directed side 22 of ridge 20 can be used to change the image of a small section of that side with the viewing angle. A carefully positioned reflecting region 70, incorporated within the profile, can be used to reflect, indicated by arrow p an image from the perturbation to appear at selected viewing angles. Such an effect might be used on every ridge of a series, or may be used selectively. For example, it could be used to give the image that from one specific viewing angle, on the ellipse shown in FIG. 5 b, a star S is twinkling.

As mentioned previously, the substrates may be formed of a wide variety of materials. For example, the substrate may be formed from a planar sheet of metal (for example galvanised steel or aluminium) or other material, which is passed through a machine, which deforms the sheet to a corrugated form to provide the successive ridges. The colouring may be applied subsequently. Instead, the colouring may be applied initially, e.g. by printing onto one side of a planar sheet of polymeric material (e.g. biodegradable polycarbonate), which is then deformed to corrugated form.

The colouring D and L may comprise areas of plain colouring, or may be patterned. Moreover, the colouring preferably comprises pictorial images (which may incorporate lettering), whether of figurative, landscape, architectural or commercial nature (e.g. company logos). An example of such pictorial images is given in FIG. 5 and has previously been described. This arrangement can be used to give changing images and an illusion of movement as an observer passes a long panel or wall etc.

1. A structure, substrate or other article having a profiled surface comprising a plurality of profiled, in a length direction extending ridges, each ridge having a peak and on opposite sides of the peak a sloping side and an opposite, downwardly directed side,
wherein the downwardly directed side comprises an undercutting part which is directed back under the peak of the ridge and
wherein the undercutting part extends from a most forward point where the undercutting starts to a valley, wherein 0.1 M≦d≦0.9 M,
wherein M is the distance between the most forward point of the peak and the sloping side of an adjacent ridge or an imaginary extension thereof and
d is the largest distance in a plane perpendicular to the length direction between the downwardly directed side and a line drawn perpendicular to the sloping side of the adjacent ridge or extension thereof, and connected to the most forward point.

2. A structure, substrate or other article according to claim 1, wherein 0.1 M≦d≦0.6 M.

3. A structure, substrate or other article having a profiled surface comprising a plurality of profiled, in a length direction extending ridges, each ridge having a peak and on opposite sides of the peak a sloping side and an opposite, downwardly directed side,
wherein the downwardly directed side comprises an undercutting part which is directed back under the peak of the ridge and
wherein the undercutting part extends from a most forward point where the undercutting starts to a valley, in particular a structure, substrate or other article according to claim 1, wherein the sloping side and the downwardly directed side are connected at the peak by a curved transition region extending between the sloping side and the undercutting part.

4. A structure, substrate or other article according to claim 3, wherein the curved transition region is convex curved with a radius R which satisfies the condition 0.05 M≦R≦0.25 M, wherein M is the distance between the most forward point of the peak and the sloping side of an adjacent ridge or an imaginary extension thereof.

5. A structure, substrate or other article according to claim 4, wherein 0.05 M≦R≦0.15 M.

6. A structure, substrate or other article having a profiled surface comprising a plurality of profiled, in a length direction extending ridges, each ridge having a peak and on opposite sides of the peak a sloping side and an opposite, downwardly directed side,
wherein the downwardly directed side comprises an undercutting part which is directed back under the peak of the ridge and
wherein the undercutting part extends from a most forward point where the undercutting starts to a valley, in particular a structure, substrate or other article according to claim 1,
wherein the acute angle T between a line connecting lowest points of successive ridges on the one hand and the direction of the sloping side on the other hand satisfies the condition 15°≦T≦40°.

7. A structure, substrate or other article according to claim 6, wherein T satisfies the condition 20°≦T≦25°.

8. A structure, substrate or other article according to claim 1, wherein the sloping side and the downwardly directed side meet at an acute angle to each other.

9. A structure, substrate or other article according to claim 1, wherein the undercutting part of the downwardly directed side is curved.

10. A structure, substrate or other article according to claim 1, wherein the undercutting part of the downwardly directed side is concave-curved.

11. A structure, substrate or other article according to claim 1, wherein the sloping side and the downwardly directed side of at least one ridge present at least partly coloured or patterned areas or images in a contrasting manner.

12. A structure, substrate or other article according to claim 1, wherein the sloping sides and/or the downwardly directed sides are provided with colouring or patterning which form a pictorial image.

13. A structure, substrate or other article according to claim 1, wherein at least one downwardly directed side or sloping side has regions with distinct optical, physical or mechanical properties.

14. A structure, substrate or other article according to claim 1, wherein the pitch and/or the shape and/or the optical properties and/or the material of the ridges present on the profiled surface vary with the position of the ridges in the structure, substrate or other article.

15. A structure, substrate or other article according to claim 1, wherein the structure, substrate or other article is manufactured through extrusion of a metal or a polymeric material.

16. A structure, substrate or other article according to claim 1, wherein the structure, substrate or other article is applied to a carrier wherein the structure, substrate, other article or substrate is at least for a part translucent and wherein between the carrier and the structure, substrate or other article a coloured pattern or image bearing intermediate layer is applied.

17. A structure, substrate or other article according to claim 1, wherein coloured, patterned or image bearing areas are embedded in at least one of the sloping sides and/or downwardly directed sides.

18. A structure, substrate or other article according to claim 1, wherein the structure, substrate or other article is provided with means for projecting coloured or patterned areas on at least one of the sloping sides and/or downwardly directed sides.

19. A structure, substrate or other article according to claim 1, wherein the structure, substrate or other article has the form of a panel and at least two panels are provided with coupling means for coupling two or more panels.

20. A structure, substrate or other article according to claim 1, wherein at least one of the downwardly directed side and sloping side of at least one ridge is provided with a photovoltaic element.

21. Method for the manufacture of a structure, substrate or other article according to claim 1, wherein a sheet or strip shaped product is rolled into the structure, substrate or other article.

22. Method according to claim 21, wherein prior to rolling, the sheet or strip shaped product is provided with a coloured, patterned or image bearing layer or a photovoltaic elements comprising layer such that after rolling a desired optical or photovoltaic effect is achieved.

23. A structure, substrate or other article according to claim 1, wherein 0.1 M≦d≦0.4 M.

24. A structure, substrate or other article according to claim 1, wherein the structure, substrate or other article is manufactured through extrusion of aluminium.
